(19) United States
(12) Patent Application Publication
(10) Pub. No.: US 2009/0058475 A1
(43) Pub. Date: Mar. 5, 2009

(54) APPARATUS AND METHOD FOR DIGITAL FREQUENCY UP-CONVERSION

(75) Inventor: Yo-An Jung, Gyeonggi-do (KR)

Correspondence Address: AMPACC LAW GROUP, 13024 Beverly Park Road, Suite 205, Mukilteo, WA, 98275, US

(73) Assignee: POSDATA CO., LTD., Seongnam-si (KR)

(21) Appl. No.: 12/294,239

(22) PCT Filed: Mar. 30, 2007
(86) PCT No.: PCT/KR2007/001566

§ 371 Date: Sep. 23, 2008

(30) Foreign Application Priority Data
Mar. 30, 2006 (KR) 10-2006-0029196

(51) Int. Cl. H03B 19/00; H03M 1/66

(52) U.S. Cl. 327/113; 341/144

(57) ABSTRACT

Disclosed is an apparatus and a method for up-converting frequencies of digital Intermediate Frequency (IF) signals input through at least two paths, and then outputting IF signals to which at least two frequencies are allocated in a communication system. The apparatus includes Serializer/Deserializers (SerDeses), down-converters, up-converters, a signal adder, a Digital-to-Analog Converter (DAC), and a Band-Pass Filter (BPF), etc. In relation to digital IF signals respectively input through at least two paths, first, the frequency down-conversion is performed, and then, the up-conversion to relatively low frequencies is performed.

### TECHNICAL FIELD

The present invention relates to an apparatus and a method for digital frequency up-conversion, and more particularly to an apparatus and a method for up-converting respectively frequencies of digital Intermediate Frequency (IF) signals input through at least two paths, and then outputting IF signals to which at least two frequencies are allocated in a communication system.

### BACKGROUND ART

FIG. 1 is a block diagram illustrating the structure of an apparatus for analog IF up-conversion according to prior art. The apparatus for analog IF up-conversion illustrated in FIG. 1 exemplifies a device which up-converts each analog IF signal, after converting each of the digital IF signals inputted through three different paths into an analog IF signal, sums up three analog IF signals, and provides a composite analog IF signal to which three Frequencies are Allocated (hereinafter, referred to as “FA”).

As illustrated in FIG. 1, the apparatus for analog IF up-conversion includes Serializer/Deserializers (SerDeses), Digital-to-Analog Converters (DACs), Local Oscillators (LOs), mixers, Band-Pass Filters (BPFs), a coupler, etc.

First, the SerDeses 111, 112, and 113 convert digital IF signals transmitted in series from channel cards into parallel signals, and transmit the converted digital IF signals to the DACs. Namely, the first SerDes 111 converts the first series digital IF signal transmitted from the first channel card into the parallel signal, and transmits the converted first digital IF signal to the first DAC 121. The second SerDes 112 converts the second series digital IF signal transmitted from the second channel card into the parallel signal, and transmits the converted second digital IF signal to the second DAC 122. The third SerDes 113 converts the third series digital IF signal transmitted from the third channel card into the parallel signal, and transmits the converted third digital IF signal to the third DAC 123.

Each of the first, second, and third digital IF signals correspond to a digital signal of n (n is a natural number) bits to which one Frequency is Allocated (hereinafter, referred to as “1 FA”). Hereinafter, to facilitate the following description, let the center frequency f_{O} equal 15 [MHz].

The DAC 121, 122, and 123 converts digital IF signals of n bits, transmitted from SerDeses, into analog IF signals having f_{O}=15 [MHz]. Namely, the first, second, and third DAC 121, 122, and 123 convert the first, second, and third digital IF signals provided from the first, second, and third SerDeses into the first, second, and third analog IF signals which respectively have the center frequencies of f_{O}=15 [MHz], and provide the first, second, and third analog IF signals to the first, second, and third mixers.

Meanwhile, each of the local oscillators 131, 132, and 133 generate a local frequency for up-conversion, and provide the generated local frequency to the relevant mixer. Namely, the first local oscillator 131 generates a first local frequency f_{L1}, and provides the first local frequency f_{L1} to the first mixer 141. The second local oscillator 132 generates a second local frequency f_{L2}, and provides the second local frequency f_{L2} to the second mixer 142. The third local oscillator 133 generates a third local frequency f_{L3}, and provides the third local frequency f_{L3} to the third mixer 143. The first, second, and third local frequencies correspond to maximum frequency limits (or magnitudes) related to the first, second, and third analog IF signals, respectively and in order to finally produce a composite analog IF signal to which three Frequencies are Allocated (hereinafter, referred to as “3 FA”), the first, second, and third local frequencies are set to different values. In the same manner, to facilitate the following description, let f_{L1}, f_{L2}, and f_{L3} equal 101 [MHz], 110 [MHz], and 119 [MHz], respectively. Also, the local oscillator is embodied including a Phase-Locked Loop (PLL) in order to provide the stable frequency without being affected by the ambient environment (i.e., ambient circuits, ambient devices, temperature, weather, etc.).

Each of the mixers 141, 142, and 143 mixes the analog IF signal of f_{O}=15 [MHz] provided from the DAC and the local frequency f_{L} provided from the local oscillator. Namely, the first mixer mixes the first analog IF signal from the first DAC and the first local frequency from the first local oscillator, and produces a first analog IF signal up-converted into the frequency corresponding to the sum (i.e., f_{O1}=f_{O}+f_{L1}). The second mixer mixes the second analog IF signal from the second DAC and the second local frequency from the second local oscillator, and produces a second analog IF signal up-converted into the frequency corresponding to the sum (i.e., f_{O2}=f_{O}+f_{L2}). The third mixer mixes the third analog IF signal from the third DAC and the third local frequency from the third local oscillator, and produces a third analog IF signal up-converted into the frequency corresponding to the sum (i.e., f_{O3}=f_{O}+f_{L3}).

The analog IF signals provided from the mixers pass through band-pass filters 151, 152, and 153, which have excellent cut-off characteristics, and accordingly, harmonic components thereof are eliminated from the analog IF signals. Based on the above-stated assumption, e.g., the first band-pass filter 151 can be embodied to be f_{O1}=116 [MHz] and Band Width (BW)=10 [MHz], the second band-pass filter 152 to be f_{O2}=125 [MHz] and BW=10 [MHz], and the third band-filter 153 to be f_{O3}=134 [MHz] and BW=10 [MHz].

The first, second, and third analog IF signals, which pass through the first, second, and third band-pass filters, are summed (i.e., analog summing) by the coupler 160, pass through a tail-end (e.g., a 3 FA band-pass filter 170 embodied with f_{OA}=125 [MHz] and BW=30 [MHz]), and finally, a up-converted 3 FA composite analog IF signal is output.

Still, as the number of up-conversion paths and local oscillators (i.e., PLL) increases by allocation of frequencies FA in the apparatus and the method for analog IF up-conversion according to prior art, problems appear in that the apparatus becomes complex, and that it needs much time to perform debugging. Moreover, harmonic components by modulation can affect other frequencies, and, it is problematic that a group delay and the degradation of phase characteristics is caused in a case where a band-pass filter having excellent cut-off characteristics is utilized. Besides, in a case where control is performed by allocation of frequencies (e.g., in the case of a change to 1 FA, 2 FA, and 3 FA), problems appear in that it is difficult to implement the control since a local output of a PLL can be generated.

In the meantime, owing to the rapid growth of technological development in a field of semiconductors, recently, an Analog-to-Digital Converter (ADC) and a Digital-to-Analog Converter (DAC) whose sampling rates are nearly 100 [Msps] have been developed, and accordingly, the direct digital conversion between an IF band signal and a baseband signal can be implemented. In addition, as the performances of digital signal processing devices such as a general-purpose Digital Signal Processor (DSP) and a Field Programmable Gate Array (FPGA) become further improved, it is possible to embody both a baseband modem that can be reconfigured in a form of software and an improved signal processing module.

However, despite the progress of digital signal processing technology, in a case where the apparatus for analog IF up-conversion according to the aforementioned prior art is directly embodied by an apparatus for digital IF conversion, as a system clock of high-frequency should be used in order to actualize a digital IF having high-frequency approaching 100 [MHz], there still exist problems such that the configuration and design of the apparatus are complex, and an embodiment thereof is difficult.

### DISCLOSURE OF INVENTION

### Technical Problem

Accordingly, the present invention has been made to solve the above problems occurring in the prior art, and it is an aspect of the present invention to provide an apparatus and a method for digital frequency up-conversion, which up-convert digital IF signals respectively input through at least two paths into digital signals respectively having relatively low frequencies, sum up up-converted digital signals, and output a composite IF signal to which at least two frequencies are allocated.

It is another aspect of the present invention to provide an apparatus and a method for digital frequency up-conversion, which down-convert digital IF signals respectively input through at least two paths into baseband signals, up-convert the baseband signals into signals having predetermined frequencies, sum up up-converted baseband signals, and output a composite IF signal to which at least two frequencies are allocated.

Furthermore, it is another aspect of the present invention to provide an apparatus and a method for digital frequency up-conversion whose configuration and design are simple, and whose debugging is easy.

### Technical Solution

In accordance with one aspect of the present invention, there is provided an apparatus for digital frequency up-conversion according to an embodiment of the present invention, including: a first down-converter for receiving a first digital signal of the center frequency f_{O1} and converting the received first digital signal into a first digital signal of the center frequency f_{OD1} lower than f_{O1}; a second down-converter for receiving a second digital signal of the center frequency f_{O2} and converting the received second digital signal into a second digital signal of the center frequency f_{OD2} lower than f_{O2}; a first up-converter for receiving a first digital signal of the center frequency f_{OD1} and converting the received first digital signal into a first digital signal of the center frequency f_{OU1} higher than f_{O1}; a second up-converter for receiving a second digital signal of the center frequency f_{OD2} and converting the received second digital signal into a second digital signal of the center frequency f_{OU2} higher than f_{O2}; and an signal adder for summing up the first digital signal of the center frequency f_{OU1} and the second digital signal of the center frequency f_{OU2}, and outputting a composite digital signal having the center frequencies f_{OU1} and f_{OU2}.

In accordance with another aspect of the present invention, there is provided an apparatus for digital frequency up-conversion according to an embodiment of the present invention, including: a Serializer/Deserializer (SerDes) for receiving at least two digital signals having a first center frequency f_{O} in series and converting the received digital signals into parallel digital signals; a Field Programmable Gate Array (FPGA) for receiving at least two digital signals provided from the SerDes, respectively converting the received at least two digital signals into at least two digital signals having the second center frequency f_{OD} lower than the first center frequency, respectively converting at least two digital signals having the second center frequency f_{OD} into at least two digital signals respectively having the center frequencies higher than the first center frequency and different from each other, summing up at least two digital signals respectively having the center frequencies higher than the first center frequency and different from each other, and outputting a composite digital signal having the at least two center frequencies; a Digital-to-Analog Converter (DAC) for converting the composite digital signal having at least two center frequencies provided from the FPGA into a composite analog signal having at least two center frequencies higher than the center frequencies of the composite digital signal, and outputting the composite analog signal; and a band-pass filter for filtering the composite analog signal.

In accordance with another aspect of the present invention, there is provided an method for digital frequency up-conversion according to an embodiment of the present invention, including the steps of: (a) converting a first digital signal of the center frequency f_{O1} into a first digital signal of the center frequency f_{OD1} lower than f_{O1}, and converting a second digital signal of the center frequency f_{O2} into a second digital signal of the center frequency f_{OD2} lower than f_{O2}; (b) converting the first digital signal of the center frequency f_{OD1} into a first digital signal of the center frequency f_{OU1} higher than f_{O1}, and converting the second digital signal of the center frequency f_{O2} into a second digital signal of the center frequency f_{OU2} higher than f_{O2}; and (c) summing up the first digital signal of the center frequency f_{OU1} and the second digital signal of the center frequency f_{OU2}, and generating a composite digital signal having the center frequencies f_{OU1} and f_{OU2}.

### ADVANTAGEOUS EFFECTS

An apparatus and a method for digital frequency up-conversion according to the present invention, first, down-convert the digital IF signals, up-convert down-converted digital IF signals into signals having relatively low frequencies, and sum up up-converted signals, in case of up-converting digital IF signals respectively input through at least two paths, and then, summing up up-converted digital signals. Accordingly, as the frequency of a system clock is lowered, power consumption and expenses can be reduced.

Also, the apparatus and a method for digital frequency up-conversion according to the present invention can prevent the deterioration of signal characteristics caused by harmonic components generated in the prior analog signal processing scheme by using the technology of digital signal processing, and therefore, can improve the quality of an output signal.

Moreover, it is simple to configure and design the apparatus for digital frequency up-conversion according to the present invention by using a Field-Programmable Gate Array (FPGA) that can be reconfigured, and accordingly, it is easy to debug the apparatus.

### BRIEF DESCRIPTION OF THE DRAWINGS

The above and other exemplary features, aspects, and advantages of the present invention will be more apparent from the following detailed description taken in conjunction with the accompanying drawings, in which:

FIG. 1 is a block diagram illustrating the structure of an apparatus for analog IF up-conversion according to the prior art;

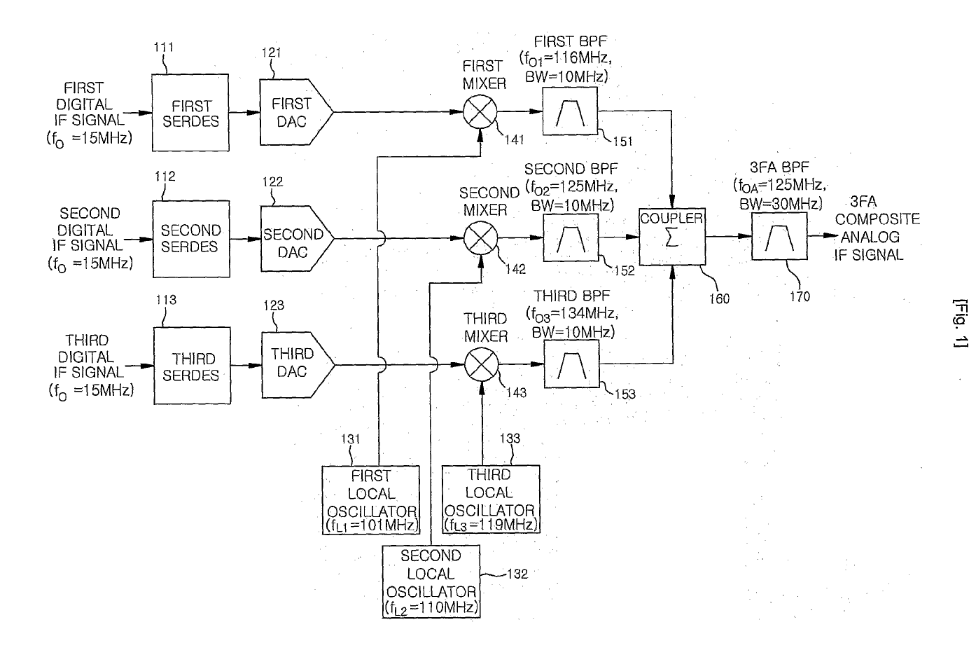

FIG. 2 is a block diagram illustrating the structure of an apparatus for digital frequency up-conversion according to an embodiment of the present invention;

FIGS. 3a to 3c are views illustrating a process for performing the digital frequency up-conversion by each frequency;

FIG. 4 is a block diagram illustrating the structure of an apparatus for digital frequency up-conversion according to another embodiment of the present invention;

FIGS. 5a and 5b are views illustrating examples in which the apparatus for digital frequency up-conversion illustrated in FIG. 4 is embodied by using a MATrix LABoratory (MATLAB) system generator;

FIG. 6 is a flowchart illustrating a method for digital frequency up-conversion according to an exemplary embodiment of the present invention; and

FIGS. 7a and 7b are detailed flowcharts illustrating the method for digital frequency up-conversion illustrated in FIG. 6.

### MODE FOR THE INVENTION

Hereinafter, an exemplary embodiment of the present invention will be described in detail with reference to the accompanying drawings. Well known functions and constructions are not described in detail since they would obscure the invention in unnecessary detail.

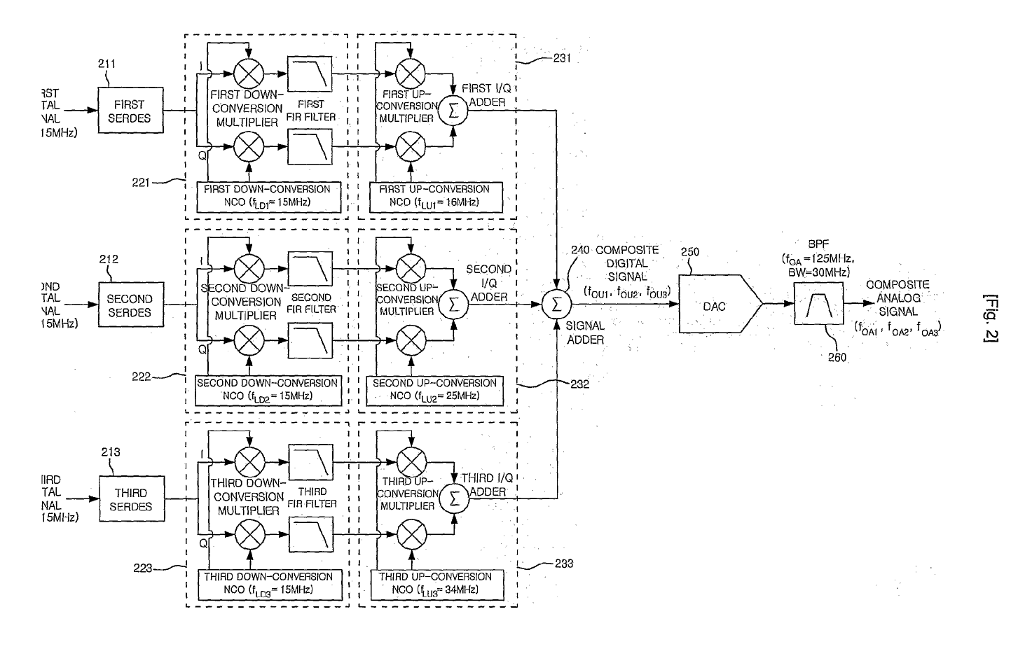

FIG. 2 is a block diagram illustrating the structure of an apparatus for digital frequency up-conversion according to an embodiment of the present invention. The present invention can be applied to a digital frequency up-conversion apparatus for outputting a signal to which at least two frequencies are allocated, and the present embodiment is produced by applying the principles of the present invention to an apparatus for digital frequency up-conversion that outputs a signal to which three frequencies are allocated.

As illustrated in FIG. 2, the apparatus for digital frequency up-conversion according to the present invention includes SerDeses 211, 212 and 213, down-converters 221, 222 and 223, up-converters 231, 232 and 233, a signal adder 240, an DAC 250, and a band-pass filter 260, etc.

The SerDeses 211, 212 and 213 converts respectively a digital IF signal transmitted in series into a parallel signal, and a converted digital IF signal is provided to each down-converter. Namely, the first SerDes 211 converts a first digital signal of the center frequency f_{O1} transmitted in series into a parallel signal, and provides a converted first digital signal to the first down-converter. The second SerDes 212 converts a second digital signal of the center frequency f_{O2} transmitted in series into a parallel signal, and provides a converted second digital signal to the second down-converter. The third SerDes 213 converts a third digital signal of the center frequency f_{O3} transmitted in series into a parallel signal, and provides a converted third digital signal to the third down-converter. The first, second, and third digital signals can be provided from, e.g., first, second, and third channel cards, and correspond to digital signals of n (n is natural number) bits, having the center frequencies f_{O1}, f_{O2}, and f_{O3}, respectively. Even though the center frequencies f_{O1}, f_{O2}, and f_{O3} are not necessarily set to the same value, the center frequencies f_{O1}, f_{O2}, and f_{O3} are usually set and use to the same value, and to facilitate a description to follow, in the present embodiment, the center frequencies f_{O1}, f_{O2}, and f_{O3} are all set to 15 [MHz] (the first center frequency: f_{O}).

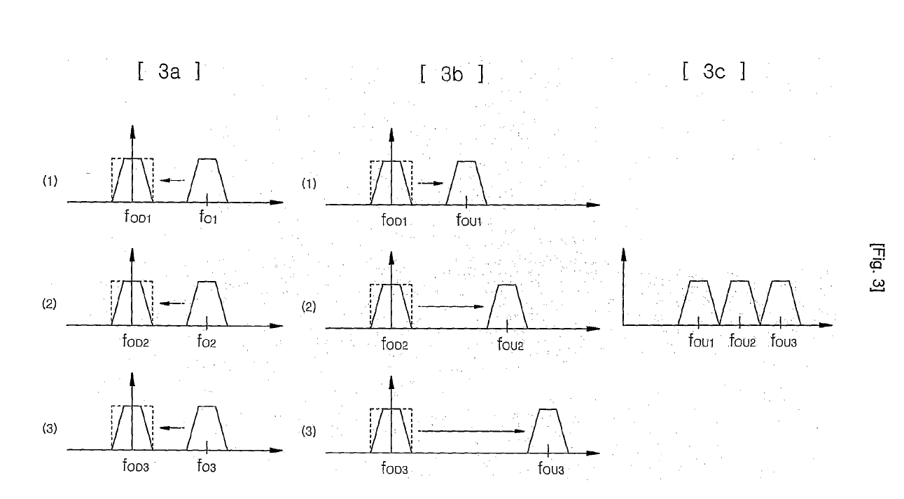

The down-converters 221, 222, and 223 down-converts respectively a frequency of digital signal provided from the SerDeses 211, 212 and 213 into a down-converted frequency (refer to FIG. 3a). Namely, the first down-converter 221 receives the first digital signal of the center frequency f_{O1}, converts the received first digital signal into a first digital signal of the center frequency f_{OD1} lower than f_{O1}, and outputs the first digital signal of the center frequency f_{OD1}. The second down-converter 222 receives the second digital signal of the center frequency f_{O2}, converts the received second digital signal into a second digital signal of the center frequency f_{OD2} lower than f_{O2}, and outputs the second digital signal of the center frequency f_{OD2}. The third down-converter 223 receives the third digital signal of the center frequency f_{O3}, converts the received third digital signal into a third digital signal of the center frequency f_{OD3} lower than f_{O3}, and outputs the third digital signal of the center frequency f_{OD3}.

For this, each down-converter includes a down-conversion Numerically Controlled Oscillator (NCO), a down-conversion multiplier, and a Finite Impulse Response (FIR) filter. Specifically, the first down-conversion NCO generates a local digital signal of a local frequency f_{LD1}, and provides the local digital signal of the local frequency f_{LD1} to the first down-conversion multiplier. The first down-conversion multiplier multiplies the first digital signal of the center frequency f_{O1} by the local digital signal of the local frequency f_{LD1}, and generates a first digital signal of the center frequency f_{OD1}=f_{O1}−f_{LD1}. Then, the first digital signal of the center frequency f_{OD1} generated in this way passes through the first FIR filter, which removes harmonic components from the first digital signal of the center frequency f_{OD1}, and output characteristics of the first digital signal are matched. Similarly, the second down-conversion NCO generates a local digital signal of a local frequency f_{LD2} and provides the local digital signal of the local frequency f_{LD2} to the second down-conversion multiplier. The second down-conversion multiplier multiplies the second digital signal of the center frequency f_{O2} by the local digital signal of the local frequency f_{LD2}, and generates a second digital signal of the center frequency f_{OD2}=f_{O2}−f_{LD2}. Then, the second digital signal of the center frequency f_{OD2} generated in this way passes through the second FIR filter. The third down-conversion NCO generates a local digital signal of a local frequency f_{LD3}, and provides the local digital signal of the local frequency f_{LD3} to the third down-conversion multiplier. The third down-conversion multiplier multiplies the third digital signal of the center frequency f_{O3} by the local digital signal of the local frequency f_{LD3}, and generates a third digital signal of the center frequency f_{OD3}=f_{O3}−f_{LD3}. Then, the third digital signal of the center frequency f_{OD3} generated in this way passes through the third FIR filter. Herein, in a case where f_{O1}=f_{LD1}, f_{O2}=f_{LD2} and f_{O3}=f_{LD3}, each of f_{OD1}, f_{OD2} and f_{OD3} becomes 0 [Hz], and the first, second, and third digital signals are down-converted into baseband signals. To facilitate a description to follow, in the present invention, f_{LD1}, f_{LD2}, and f_{LD3} are all set to 15 [MHz]. Therefore, f_{OD1}=f_{OD2}=f_{OD3}=0 [Hz] (the second center frequency: f_{OD}), the first, second, and third digital signals are down-converted into baseband signals.

The up-converters 231, 232, and 233 up-converts respectively the digital signals provided from the down-converters into up-converted signals (refer to FIG. 3b). Namely, the first up-converter 231 receives the first digital signal of the center frequency f_{OD1}, converts the received first digital signal into a first digital signal of the center frequency f_{OU1} higher than f_{O1}, and outputs the first digital signal of the center frequency f_{OU1}. The second up-converter 232 receives the second digital signal of the center frequency f_{OD2}, converts the received second digital signal into a second digital signal of the center frequency f_{OU2} higher than f_{O2}, and outputs the second digital signal of the center frequency f_{OU2}. The third up-converter 233 receives the third digital signal of the center frequency f_{OD3}, converts the received third digital signal into a third digital signal of the center frequency f_{OU3} higher than f_{O3}, and outputs the third digital signal of the center frequency f_{OU3}.

For this, each up-converter includes an up-conversion NCO and a up-conversion multiplier. In detail, the first up-conversion NCO generates a local digital signal of a local frequency f_{LU1}, and provides the local digital signal of the local frequency f_{LU1} to the first up-conversion multiplier. The first up-conversion multiplier multiplies the first digital signal of the center frequency f_{OD1} by the local digital signal of the local frequency f_{LU1}, and generates a first digital signal of the center frequency f_{OU1}=f_{OD1}+f_{LU1}. Likewise, the second up-conversion NCO generates a local digital signal of a local frequency f_{LU2}, and provides the local digital signal of the local frequency f_{LU2} to the second up-conversion multiplier. The second up-conversion multiplier multiplies the second digital signal of the center frequency f_{OD2} by the local digital signal of the local frequency f_{LU2}, and generates a second digital signal of the center frequency f_{OU2}=f_{OD2}+f_{LU2}. The third up-conversion NCO generates a local digital signal of a local frequency f_{LU3}, and provides the local digital signal of the local frequency f_{LU3} to the third up-conversion multiplier. The third up-conversion multiplier multiplies the third digital signal of the center frequency f_{OD3} by the local digital signal of the local frequency f_{LU3}, and generates a third digital signal of the center frequency f_{OU3}=f_{OD3}+f_{LU3}. The local frequencies f_{LU1}, f_{LU2}, and f_{LU3} are respectively set to different values so as to finally generate a signal to which the three frequencies are allocated, and are desirably set so that f_{LU1}, f_{LU2}, and f_{LU3} may form an arithmetic progression. In the present invention, f_{LU1}, f_{LU2}, and f_{LU3} are respectively set to about 16 [MHz], 25 [MHz] and 34 [MHz], and because f_{OD1}=f_{OD2}=f_{OD3}=0 [Hz], f_{OU1}, f_{OU2} and f_{OU3} are respectively set to about 16 [MHz], 25 [MHz], and 34 [MHz]. Still, it will be apparent the center frequency of a signal generated in an embodiment of the present invention can be allowed in a certain error range according to ambient conditions or circumstances.

Meanwhile, in a case where a digital signal corresponds to a complex signal, an In-phase (I) component and a Quadrature-phase (Q) component are processed following the separation of the I and Q components from the complex signal, and following the performance of a required operation, the digital sum is performed by an I/Q adder. In FIG. 2, a structure in which the down-converters and the up-converters process I and Q components following the separation thereof is illustrated by different paths, and in order to avoid the use of complicated terms, a multiplier and an FIR filter which respectively process the I and Q components are not denoted by using distinguished terms.

The signal adder 240 sums up the first digital signal of the center frequency f_{OU1} from the first up-converter, the second digital signal of the center frequency f_{OU2} from the second up-converter, and the third digital signal of the center frequency f_{OU3} from the third up-converter, and produces a 3 FA composite digital signal having the center frequencies f_{OU1}, f_{OU2}, and f_{OU3} (refer to FIG. 3c).

The 3FA composite digital signal having the center frequencies f_{OU1}, f_{OU2}, and f_{OU3} is transmitted to the DAC 250, and the DAC 250 converts the received 3FA composite digital signal into a 3FA composite analog signal having the center frequencies f_{OA1}, f_{OA2}, and f_{OA3}. Specifically, the received 3FA composite digital signal is converted into an analog signal of a desired frequency bandwidth by adjusting sampling clock being used during digital-to-analog conversion, and through this, the secondary frequency up-conversion (f_{OA}>f_{OU}) can be performed. To cite an instance, in a case where a sampling clock of about f_{S}=400 [MHz] is used, and where the up-conversion of about 100 [MHZ] is necessary, as a carrier of 100 [MHZ] is generated by dividing the sampling clock by 4 (i.e., f_{S}/4 modulation), a 3FA composite analog signal (f_{OA1}=116 [MHz], f_{OA2}=125 [MHz], and f_{OA3}=134 [MHz]) having the center frequencies (100 [MHz]+16 [MHz], (100[MHz]+25 [MHz]), and (100 [MHz]+34 [MHz]) can be generated.

The 3FA composite analog signal having the center frequencies f_{OA1}, f_{OA2}, and f_{OA3} is transmitted to the band-pass filter 260 (e.g., a Surface Acoustic wave (SAW) filter). The band-pass filter filters the transmitted 3FA composite analog signal, eliminates the carrier, and can obtain a desired 3FA analog signal having 116 [MHz] (FA1), 125 [MHz] (FA2), and 134 [MHz] (FA3).

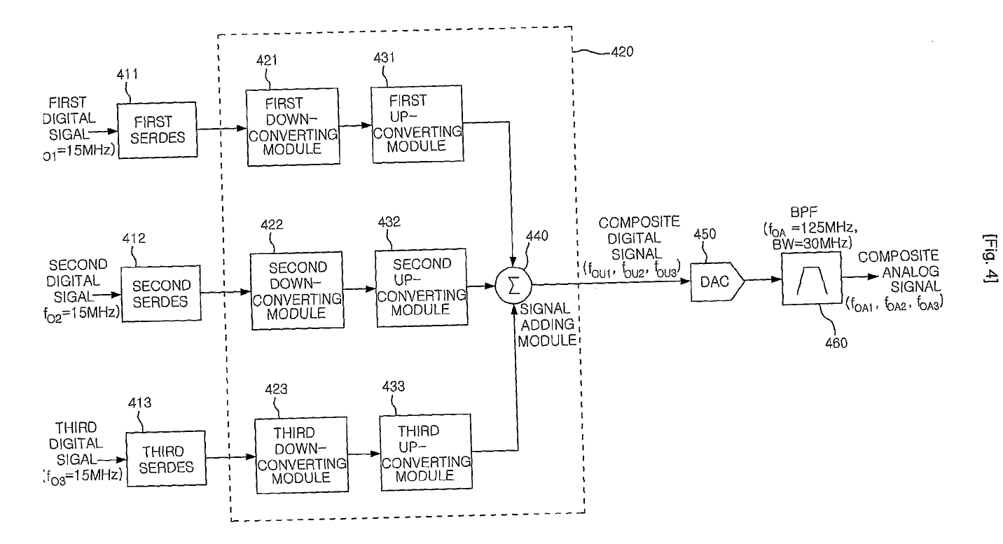

FIG. 4 is a block diagram illustrating the structure of an apparatus for digital frequency up-conversion according to another embodiment of the present invention. It is the apparatus for digital frequency up-conversion according to another embodiment of the present invention that the down-converters, the up-converters, and the signal adder are embodied by a single FPGA in the apparatus for digital frequency up-conversion which has been previously described with reference to FIG. 2.

As illustrated in FIG. 4, the apparatus for digital frequency up-conversion includes SerDeses 411, 412 and 413, an FPGA 420, an DAC 450, and a band-pass filter 460, etc. Herein, the SerDeses, the DAC, and the band-pass filter are formed in the same manner as seen in the aforementioned description with reference to FIG. 2, and hereinafter, only the FPGA 420 will be described in detail.

The FPGA corresponds to an Integrated Circuit (IC) having a feature such that the FPGA can be used to be programmed as a user's requirement arises, and in the present invention, is configured to include down-converting modules, up-converting modules, and a signal adding module.

The down-converting modules 421, 422, and 423 correspond to the down-converters illustrated in FIG. 2, and down-converts respectively digital signals provided from SerDeses into down-converted digital signals. Namely, the first, second, and third down-converting modules 421, 422, 423 respectively receive first, second, and third digital signals of the center frequencies f_{O1}, f_{O2}, and f_{O3} and respectively down-convert the received first, second, and third digital signals of the center frequencies f_{OD1}, f_{OD2}, and f_{O3} into first, second, and third digital signals of the center frequencies f_{OD1}, f_{OD2}, and f_{OD3}. For this, each down-converting module is configured to include an NCO function for down-conversion, a multiplying function for down-conversion, and a function of FIR filter.

The up-converting modules 431, 432, and 433 correspond to the up-converters illustrated in FIG. 2, and up-converts respectively digital signals provided from the down-converting modules into up-converted digital signals. Namely, the first, second, and third up-converting module 431, 432, and 433 respectively receive the first, second, and third digital signals of the center frequencies f_{OD1}, f_{OD2}, and f_{OD3}, and respectively up-convert the received first, second, and third digital signals of the center frequencies f_{OD1}, f_{OD2}, and f_{OD3} into first, second, and third digital signals of the center frequencies f_{OU1}, f_{OU2}, and f_{OU3}. For this, each up-converting module is configured to include an NCO function for up-conversion, and a multiplying function for up-conversion.

Lastly, the signal adding module 440 corresponds to the signal adder illustrated in FIG. 2, and sums up the first, second, and third digital signals of the center frequencies f_{OU1}, f_{OU2}, and f_{OU3}, respectively, and generates a 3FA composite digital signal having the center frequencies f_{OU1}, f_{OU2}, and f_{OU3}.

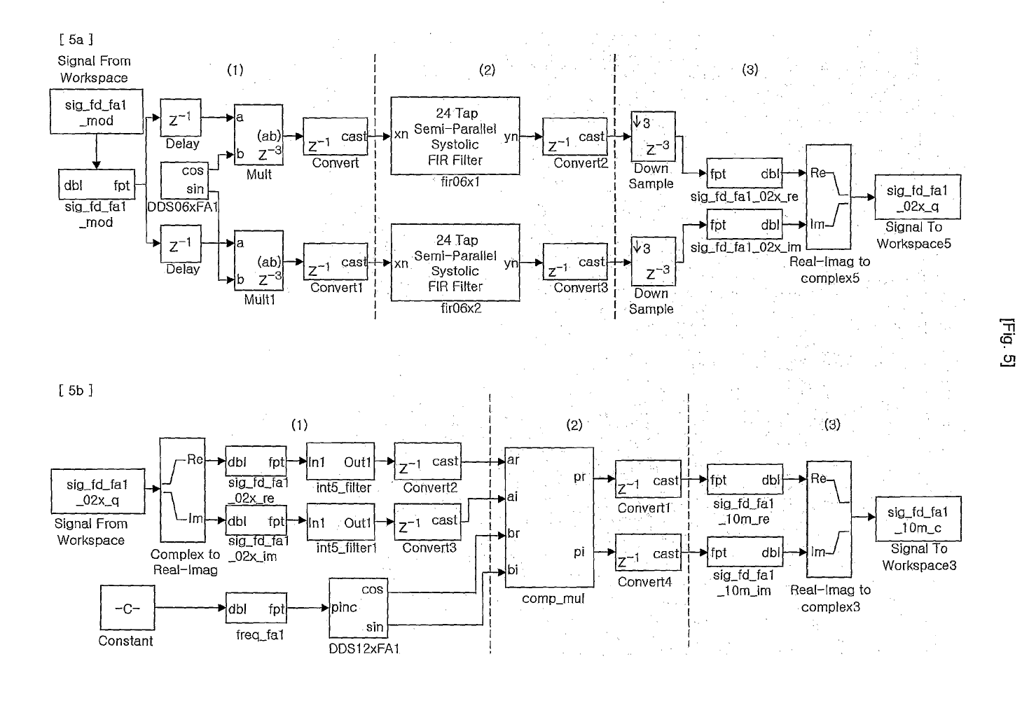

A circuit configuration based on the FPGA can be implemented by using Very high speed integrated circuit Hardware Description Language (VHDL), etc., and can be desirably accomplished by using a system generator of the MATLAB. FIGS. 5a and 5b are views illustrating a down-converting module and an up-converting module related to a 1FA digital signal, embodied by using the system generator of the MATLAB, respectively. Hereinafter, a process of a signal will be described to take as an example a case where a first digital signal (1FA) of f_{O1}=15 [MHz], f_{LD1}=15 [MHz], f_{LU1}=16 [MHz], and f_{OU1}=16 [MHz].

For starters, ‘part (1)’ illustrated in FIG. 5a converts the format of an input digital signal of the center frequency of 15 [MHz] and a data rate of 60 [Mbps] from double precision floating point to single precision floating point, separates I and Q components from a signal converted in the format of single precision floating point, multiplies each of the separated I and Q components by 15 [MHz], and accordingly generates a down-converted digital signal of a baseband.

‘Part (2)’ illustrated in FIG. 5a filters the baseband digital signal generated in this way to eliminate harmonic components. Accordingly, it is obtained to satisfy an output InterModulation and Distortion (IMD) performance. ‘Part (3)’ illustrated in FIG. 5a down-samples the baseband digital signal having a data rate of 60 [Mbps] by three times, generates a baseband digital signal having a data rate of 20 [Mbps], converts the format of the baseband digital signal having the data rate of 20 [Mbps] from single precision floating point to double precision floating point, and sums up the I component and the Q component.

Meanwhile, ‘part (1)’ illustrated in FIG. 5b separates I and Q components from the baseband digital signal having a data rate of 20 [Mbps], converts the format of the separated digital signal respectively having I and Q components from double precision floating point to single precision floating point, respectively, filters the I and Q components each of which has the converted format, and generates a local signal of 16 [MHz] for up-conversion aside from this. ‘Part (2)’ illustrated in FIG. 5b multiplies the baseband digital signal having the data rate of 20 [Mbps] by the local signal of 16 [MHz], and generates an up-converted digital signal of 16 [MHz]. Finally, ‘part (3)’ illustrated in FIG. 5b converts each of I and Q components of the up-converted digital signal of 16 [MHz] from single precision floating point to double precision floating point, and sums up the I and Q components each of which has the converted format.

For reference, in the above embodiments, the center frequency and the data rate of a digital signal inputted from the outside (e.g., channel cards) correspond to values that can be set according to interface specifications. In the case of the present embodiments, in order to process the digital signal having the center frequency of 15 [MHz] and the data rate of 60 [Mbps], the down-converter (i.e., down-converting module) uses a sampling clock of 240 [MHz]. However, since the data rate becomes 120 [Mbps] if the up-converter (i.e., up-converting module) uses the sampling clock of 240 [MHz], in a case where I/Q modulation is performed by the DAC, a carrier component of 120 [MHz] is generated in the final output. The carrier component of 120 [MHz] is in band of a 3FA frequency, and cannot be removed by a band-pass filter having the center frequency of 125 [MHz] and BW=30 [MHz]. So as to settle this, the present invention uses a method for varying system clocks of the down-converter (i.e., down-converting module) and the up-converter (i.e., up-converting module), and for changing the data rate. In particular, as previously mentioned, the down-converter (i.e., down-converting module) down-samples the digital signal having the data rate of 60 [Mbps] by three times, and changes the digital signal of 60 [Mbps] into the digital signal having the data rate of 20 [Mbps]. The up-converter (i.e., up-converting module) down-samples 100 [Mbps] by five times, and interfaces with the digital signal having the data rate of 20 [Mbps]. Therefore, if an output data rate of the up-converter (i.e., up-converting module) is set to 100 [Mbps], a carrier component of 100 [MHZ] is generated out-band of the 3FA frequency in the final output of the DAC, and this carrier component of 100 [MHZ] is eliminated by a band-pass filter.

Hereinafter, a method for digital frequency up-conversion according to the present invention will be described. As a specific process or the principles of a detailed operation can be understood with reference to the aforementioned description of the apparatus for digital frequency up-conversion, a detailed description of overlapping contents will be avoided, and a brief description will be made on the basis of steps generated in time series in the following.

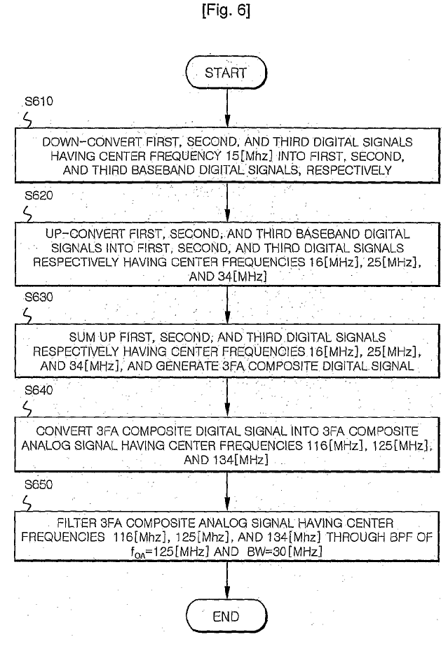

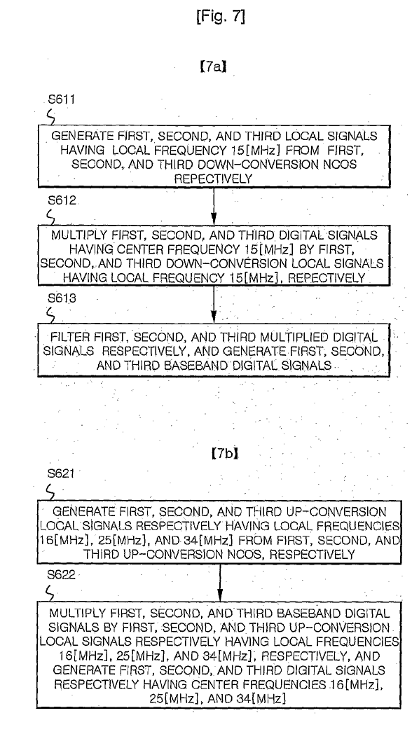

FIG. 6 is a flowchart illustrating a method for digital frequency up-conversion according to an exemplary embodiment of the present invention. FIGS. 7a and 7b are detailed flowcharts illustrating the method for digital frequency up-conversion illustrated in FIG. 6, which are applied to a method for digital frequency up-conversion that outputs a signal to which three frequencies are allocated. Herein, parameter values are used in the aforementioned apparatus for digital frequency up-conversion as follows: f_{O1}=f_{O2}=f_{O3}=15 MHz, f_{LD1}=f_{LD2}=f_{LD3}=15 MHz, f_{OD1}=f_{OD2}=f_{OD3}=0 Hz, f_{LU1}=f_{OU1}=16 MHz, f_{LU2}=f_{OU2}=25 MHz, f_{LU3}=f_{OU3}=34 MHz.

First, in step S610, the first, second, and third down-converters respectively down-convert first, second, and third digital signals respectively having the center frequencies f_{O1}, f_{O2}, and f_{O3} into first, second, and third digital signals respectively having the center frequencies f_{OD1}, f_{OD2}, and f_{OD3}. Particularly, the first, second, and third NCOs for down-conversion respectively generate first, second, and third local signals for down-conversion respectively having local frequencies f_{LD1}, f_{LD2}, and f_{LD3} (S611). Then, the first, second, and third multipliers for down-conversion respectively multiply the first, second, and third digital signals respectively having the center frequencies f_{O1}, f_{O2}, and f_{O3} by the first, second, and third local signals for down-conversion respectively having the local frequencies f_{LD1}, f_{LD2}, and f_{LD3} (S612). Multiplied signals are respectively filtered by the first, second, and third FIR filters, and then, first, second, and third digital signals respectively having the center frequencies f_{OD1}, f_{OD2}, and f_{OD3} are produced. In this case, if f_{OD1}=f_{OD2}=f_{OD3}=0 Hz, the first, second, and third digital signals becomes baseband signals.

Furthermore, in step 620, the first, second, and third up-converters respectively up-convert the first, second, and third digital signals respectively having the center frequencies f_{OD1}, f_{OD2}, and f_{OD3} into first, second, and third digital signals respectively having the center frequencies f_{OU1}, f_{OU2}, and f_{OU3}. Particularly, the first, second, and third NCOs for up-conversion respectively generate first, second, and third local signals for up-conversion respectively having local frequencies f_{LU1}, f_{LU2}, and f_{LU3} (S621). Then, the first, second, and third multipliers for up-conversion respectively multiply the first, second, and third digital signals respectively having the center frequencies f_{OD1}, f_{OD2}, and f_{OD3} by the first, second, and third local signals for up-conversion respectively having the local frequencies f_{LU1}, f_{LU2}, and f_{LU3}, and respectively generate first, second, and third digital signals respectively having the center frequencies f_{OD1}, f_{OD2}, and f_{OD3} (S622).

In step S630, the signal adder sums up the first, second, and third digital signals respectively having the center frequencies f_{OD1}, f_{OD2}, and f_{OD3}, generates a 3FA composite digital signal having the center frequencies f_{OU1}, f_{OU2}, and f_{OU3}, and provides the 3FA composite digital signal to the DAC.

In step S640, the DAC converts the 3FA composite digital signal having the center frequencies f_{OU1}, f_{OU2}, and f_{OU3} into a 3FA composite analog signal having the center frequencies f_{OA1}, f_{OA2}, and f_{OA3}, and at this time, performs the secondary up-conversion.

Lastly, in step S650, the band-pass filter filters the 3FA composite analog signal having the center frequencies f_{OA1}, f_{OA2}, and f_{OA3}, eliminates a carrier from the 3FA composite analog signal, and obtains a 3FA (i.e., 116 [MHz], 125 [MHz], and 134 [MHz]) analog signal.

While this invention has been described in connection with what is presently considered to be the most practical and preferred embodiment, it is to be understood that the invention is not limited to the disclosed embodiment and the drawings, but, on the contrary, it is intended to cover various modifications and variations within the spirit and scope of the appended claims.

1. An apparatus for digital frequency up-conversion, the apparatus comprising:
a first down-converter for receiving a first digital signal of the center frequency f_{O1} and converting the received first digital signal into a first digital signal of the center frequency f_{OD1} lower than f_{O1};
a second down-converter for receiving a second digital signal of the center frequency f_{O2} and converting the received second digital signal into a second digital signal of the center frequency f_{OD2} lower than f_{O2};
a first up-converter for receiving a first digital signal of the center frequency f_{OD1} and converting the received first digital signal into a first digital signal of the center frequency f_{OU1} higher than f_{O1};
a second up-converter for receiving a second digital signal of the center frequency f_{OD2} and converting the received second digital signal into a second digital signal of the center frequency f_{OU2} higher than f_{O2}; and
an signal adder for summing up the first digital signal of the center frequency f_{OU1} and the second digital signal of the center frequency f_{OU2}, and outputting a composite digital signal having the center frequencies f_{OU1} and f_{OU2}.

2. The apparatus as claimed in claim 1, wherein the first digital signal of the center frequency f_{OD1} and the second digital signal of the center frequency f_{OD2} correspond to baseband signals.

3. The apparatus as claimed in claim 1, which further comprises a Digital-to-Analog Converter (DAC) for converting the composite digital signal having the center frequencies f_{OU1} and f_{OU2} into a composite analog signal having the center frequencies f_{OA1} and f_{OA2} which are higher than the mean of f_{OU1} and f_{OU2}.

4. The apparatus as claimed in claim 3, which further comprises a band-pass filter for filtering the composite analog signal having the center frequencies f_{OA1} and f_{OA2}.

5. The apparatus as claimed in claim 1, further comprising:
a first Serializer/Deserializer (SerDes) for receiving the first series digital signal of the center frequency f_{O1}, converting the received first series digital signal of the center frequency f_{O1} into a first parallel digital signal, and outputting the first parallel digital signal to the first down-converter; and
a second SerDes for receiving the second digital signal of the center frequency f_{O2} in series, converting the received second digital signal of the center frequency f_{O2} into a second parallel digital signal, and outputting the second parallel digital signal to the second down-converter.

6. The apparatus as claimed in claim 1, wherein the first down-converter comprises:
a first down-conversion Numerically Controlled Oscillator (NCO) for generating a first down-conversion local signal of a local frequency f_{LD1};
a first down-conversion multiplier for multiplying the first digital signal of the center frequency f_{O1} by the first down-conversion local signal of the local frequency f_{LD1}; and
a first Finite Impulse Response (FIR) filter for filtering a first multiplied digital signal provided from the first down-conversion multiplier, and outputting a first digital signal of the center frequency f_{OD1}=f_{O1}−f_{LD1},
and wherein the second down-converter comprises:
a second down-conversion NCO for generating a second down-conversion local signal of a local frequency f_{LD2};
a second down-conversion multiplier for multiplying the second digital signal of the center frequency f_{O2} by the second down-conversion local signal of the local frequency f_{LD2}; and
a second FIR filter for filtering a second multiplied digital signal provided from the second down-conversion multiplier, and outputting a second digital signal of the center frequency f_{OD2}=f_{O2}−f_{LD2}.

7. The apparatus as claimed in claim 6, wherein the first up-converter comprises:
a first up-conversion NCO for generating a first up-conversion local signal of a local frequency f_{LU1}; and
a first up-conversion multiplier for multiplying the first digital signal of the center frequency f_{OD1} by the first up-conversion local signal of the local frequency f_{LU1},
and wherein a second up-converter comprises:
a second up-conversion NCO for generating a second up-conversion local signal of a local frequency f_{LU2}; and
a second up-conversion multiplier for multiplying the second digital signal of the center frequency f_{OD2} by the second up-conversion local signal of the local frequency f_{LU2}.

8. The apparatus as claimed in claim 7, wherein the first down-converter and the first up-converter perform conversions by separating an In-phase (I) component and a Quadrature-phase (Q) component from the first digital signal, and the second down-converter and the second up-converter perform conversions by separating an I component and a Q component from the second digital signal.

9. The apparatus as claimed in claim 1, further comprising:
a third down-converter for receiving a third digital signal of the center frequency f_{O3}, and outputting a third digital signal of the center frequency f_{OD3} lower than f_{O3}; and
a third up-converter for receiving the third digital signal of the center frequency f_{OD3}, and outputting a third digital signal of the center frequency f_{OU3} higher than f_{O3};
and wherein the signal adder sums up the first, second, and third digital signals respectively having the center frequencies f_{OU1}, f_{OU2}, and f_{OU3}, and outputs a composite digital signal having the center frequencies f_{OU1}, f_{OU2}, and f_{OU3}.

10. The apparatus as claimed in claim 9, wherein the first, second, and third digital signals respectively having the center frequencies f_{OD1}, f_{OD2}, and f_{OD3} correspond to baseband signals.

11. The apparatus as claimed in claim 9, wherein the center frequencies f_{OU1}, f_{OU2}, and f_{OU3} of the composite digital signal form an arithmetic progression.

12. The apparatus as claimed in claim 11, wherein the center frequencies f_{OU1}, f_{OU2}, and f_{OU3} correspond to about 16 MHz, 25 MHz, and 34 MHz, respectively.

13. The apparatus as claimed in claim 12, which further comprises an Digital-to-Analog Converter (DAC) for converting a composite digital signal having the center frequencies f_{OU1}, f_{OU2}, and f_{OU3} respectively corresponding to about 16 MHz, 25 MHz, and 34 MHz into a composite analog signal having the center frequencies f_{OA1}, f_{OA2}, and f_{OA3} respectively corresponding to about 116 MHz, 125 MHz, and 134 MHz, and outputting the composite analog signal.

14. The apparatus as claimed in claim 13, wherein the DAC performs digital-to-analog conversion by using a signal generated by dividing a sampling clock of 400 MHz by 4.

15. The apparatus as claimed in claim 13, wherein data rates of the first, second, and third digital signals respectively having the center frequencies f_{O1}, f_{O2}, and f_{O3} are equal to about 60 Mbps,
data rates of the first, second, and third digital signals respectively having the center frequencies f_{OD1}, f_{OD2}, and f_{OD3}, respectively provided from the first, second, and third down-converters are equal to about 20 Mbps, and
data rates of the first, second, and third digital signals respectively having the center frequencies f_{OU1}, f_{OU2}, and f_{OU3}, respectively provided from the first, second, and third up-converters are equal to about 100 Mbps.

16. An apparatus for digital frequency up-conversion, the apparatus comprising:
a Serializer/Deserializer (SerDes) for receiving at least two digital signals having a first center frequency f_{O} in series and converting the received digital signals into parallel digital signals;
a Field Programmable Gate Array (FPGA) for receiving at least two digital signals provided from the SerDes, respectively converting the received at least two digital signals into at least two digital signals having the second center frequency f_{OD} lower than the first center frequency, respectively converting at least two digital signals having the second center frequency f_{OD} into at least two digital signals respectively having the center frequencies higher than the first center frequency and different from each other, summing up at least two digital signals respectively having the center frequencies higher than the first center frequency and different from each other, and outputting a composite digital signal having the at least two center frequencies;
a Digital-to-Analog Converter (DAC) for converting the composite digital signal having at least two center frequencies provided from the FPGA into a composite analog signal having at least two center frequencies higher than the center frequencies of the composite digital signal, and outputting the composite analog signal; and
a band-pass filter for filtering the composite analog signal.

17. The apparatus as claimed in claim 16, wherein the FPGA comprises:
a down-converting module for respectively converting at least two digital signals having the first center frequency into at least two digital signals having the second center frequency lower than the first center frequency;
an up-converting module for respectively converting at least two digital signals having the second center frequency into at least two digital signals respectively having the center frequencies which are higher than the first center frequency, and which are not only separated at a predetermined interval but also different from each other; and
a signal adding module for adding the at least two digital signals respectively having the center frequencies different from each other, and outputting a composite digital signal having at least two center frequencies.

18. The apparatus as claimed in claim 16, wherein the at least two digital signals having the second center frequency correspond to baseband signals.

19. The apparatus as claimed in claim 16, wherein the center frequencies of the composite digital signal form an arithmetic progression.

20. The apparatus as claimed in claim 16, wherein the FPGA performs conversion by separating an I component and a Q component from each of the digital signals.

21. The apparatus as claimed in claim 16, wherein the FPGA is configured by using a system generator of MATrix LABoratory (MATLAB).

22. A method for digital frequency up-conversion, the method comprising the steps of:
(a) converting a first digital signal of the center frequency f_{O1} into a first digital signal of the center frequency f_{OD1} lower than f_{O1}, and converting a second digital signal of the center frequency f_{O2} into a second digital signal of the center frequency f_{OD2} lower than f_{O2};
(b) converting the first digital signal of the center frequency f_{OD1} into a first digital signal of the center frequency f_{OU1} higher than f_{O1}, and converting the second digital signal of the center frequency f_{OD2} into a second digital signal of the center frequency f_{OU2} higher than f_{O2}; and
(c) summing up the first digital signal of the center frequency f_{OU1} and the second digital signal of the center frequency f_{OU2}, and generating a composite digital signal having the center frequencies f_{OU1} and f_{OU2}.

23. The method as claimed in claim 22, which further comprises a step of (d) converting the composite digital signal having the center frequencies f_{OU1} and f_{OU2} into a composite analog signal having the center frequencies f_{OA1} and f_{OA2} which are higher than the mean of f_{OU1} and f_{OU2}.

24. The method as claimed in claim 23, which further comprises a step of (e) filtering the composite analog signal having the center frequencies f_{OA1} and f_{OA2}.

25. The method as claimed in claim 22, wherein step (a) comprises the steps of:
(a-1) generating a first down-conversion local signal of a local frequency f_{LD1} and a second down-conversion local signal of a local frequency f_{LD2};
(a-2) multiplying the first digital signal of the center frequency f_{O1} by the first down-conversion local signal of the local frequency f_{LD1}, and multiplying the second digital signal of the center frequency f_{O2} by the second down-conversion local signal of the local frequency f_{LD1}; and
(a-3) filtering the first and second multiplied digital signals, respectively, and outputting a first digital signal of the center frequency f_{OD1}=f_{O1}−f_{LD1} and a second digital signal of the center frequency f_{OD2}=f_{O2}−f_{LD2}.

26. The method as claimed in claim 24, wherein step (b) comprises the steps of:
(b-1) generating a first up-conversion local signal of a local frequency f_{LU1} and a second up-conversion local signal of a local frequency f_{LU2}; and
(b-2) multiplying the first digital signal of the center frequency f_{OD1} by the first up-conversion local signal of the local frequency f_{LU1}, and multiplying the second digital signal of the center frequency f_{OD2} by the second up-conversion local signal of the local frequency f_{LU2}.

27. The method as claimed in claim 22, wherein the first digital signal of the center frequency f_{OD1} and the second digital signal of the center frequency f_{OD2} correspond to baseband signals.
